(19) United States
(12) Patent Application Publication
(10) Pub. No.: US 2025/0070033 A1
(43) Pub. Date: Feb. 27, 2025

(54) SEMICONDUCTOR PACKAGE WITH VARIABLE SOLDER RESIST OPENING DIMENSIONS AND METHODS FOR FORMING THE SAME

(71) Applicant: Taiwan Semiconductor Manufacturing Company Limited, Hsinchu (TW)

(72) Inventors: Tsung-Yen Lee, Hemei Township (TW); Chia-Kuei Hsu, Hsinchu City (TW); Ming-Chih Yew, Hsinchu City (TW); Shin-Puu Jeng, Po-Shan Village (TW)

(21) Appl. No.: 18/452,601

(22) Filed: Aug. 21, 2023

(51) Int. Cl. H01L 23/538; H01L 25/00; H01L 25/065; H10B 80/00

(52) U.S. Cl. CPC H01L 23/5386; H01L 23/5383; H01L 23/5385; H01L 25/0655; H01L 25/50; H10B 80/00; H01L 24/16; H01L 24/32; H01L 24/73; H01L 2224/16227; H01L 2224/32225; H01L 2224/73204

(57) ABSTRACT

Semiconductor packages and methods of fabricating semiconductor packages include a package substrate having an outer coating layer, such as solder resist layer. A plurality of openings through the outer coating layer of the package substrate expose an array of bonding pads used to bond a package structure, including an interposer and at least one semiconductor IC die, to the package substrate. The openings through the outer coating layer of the package substrate include non-uniform dimensions in different regions of the package substrate. The non-uniform dimensions of the openings through the outer coating layer of the package substrate may help to mitigate against warpage of the interposer and thereby provide improved bonding connections between the bonding pads of the package substrate and corresponding bonding structures on the interposer of the package structure.

### BACKGROUND

Semiconductor devices are used in a variety of electronic applications. Some example uses may include personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer, and individual dies on the wafer are singulated by sawing between the integrated circuits along a scribe line. The individual dies are typically packaged separately, for example, in multi-chip modules, or in other types of packaging.

As semiconductor packages have become more complex, ensuring mechanical integrity of the package, including the electrical interconnections between various components of the package, has become more difficult.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-section view of an exemplary intermediate structure during a process of forming a semiconductor package including an organic interposer located over a first carrier substrate according to various embodiments of the present disclosure.

FIG. 2 is a vertical cross-section view of the exemplary intermediate structure showing bonding structures located over the first side surface of the interposer according to various embodiments of the present disclosure.

FIG. 3A is a vertical cross-section view of the exemplary intermediate structure showing a plurality of semiconductor integrated circuit (IC) dies mounted over the first side surface of the interposer according to various embodiments of the present disclosure.

FIG. 3B is a top view of the exemplary intermediate structure shown in FIG. 3A.

FIG. 4 is a vertical cross-section view of the exemplary intermediate structure showing a first underfill material portion located between the lower surfaces of the semiconductor IC dies and the first side surface of the interposer, and a molding portion around the outer periphery of the plurality of semiconductor IC dies according to various embodiments of the present disclosure.

FIG. 5 is a vertical cross-section view of the exemplary intermediate structure showing a second release layer located over the upper surfaces of the plurality of semiconductor dies, the exposed upper surface of the first underfill material portion and the exposed upper surface of the molding portion, and a second carrier substrate over the second release layer according to various embodiments of the present disclosure.

FIG. 6 is a vertical cross-section view of the exemplary intermediate structure showing the first carrier substrate removed according to various embodiments of the present disclosure.

FIG. 7 is a vertical cross-section view of the exemplary intermediate structure showing a plurality of bonding structures located over the second side surface of the interposer according to various embodiments of the present disclosure.

FIG. 8 is a vertical cross-section view of an exemplary intermediate structure showing a package structure according to various embodiments of the present disclosure.

FIG. 9A is a vertical cross-section view of a package substrate according to various embodiments of the present disclosure.

FIG. 9B is a top view of the package substrate of FIG. 9A.

FIG. 9C is an enlarged vertical cross-section view of a portion of the package substrate 201 of FIGS. 9A and 9B.

FIG. 10A is a vertical cross-section view of an exemplary intermediate structure during a process of forming a semiconductor package showing a package structure mounted over the front side surface of a package substrate according to various embodiments of the present disclosure.

FIG. 10B is an enlarged vertical cross-section view of a portion of the exemplary intermediate structure of FIG. 10A.

FIG. 11 is a vertical cross-section view of a semiconductor package including a second underfill material portion located between the front side surface of the package substrate and the second side surface of the interposer according to various embodiments of the present disclosure.

FIG. 12 is a vertical cross-section view of the semiconductor package including a plurality of solder balls located on the rear side surface of the package substrate according to various embodiments of the present disclosure.

FIG. 13A is a top view of an exemplary intermediate structure illustrating an alternative layout of the plurality of semiconductor IC dies according to an embodiment of the present disclosure.

FIG. 13B is a top view of a package substrate to which a package substrate having a layout of semiconductor IC dies as shown in FIG. 13A may be mounted to form a semiconductor package according to an embodiment of the present disclosure.

FIG. 14 is a flow diagram illustrating a method of fabricating a semiconductor package according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are be directed to semiconductor devices, and in particular to semiconductor packages and methods of fabricating semiconductor packages that include a package substrate having an outer coating layer, such as solder resist layer, such that openings through the outer coating layer of the package substrate include non-uniform dimensions in different regions of the package substrate.

Typically, in a semiconductor package a number of semiconductor integrated circuit (IC) dies (i.e., “chips”) may be mounted onto a common substrate, which may also be referred to as a “package substrate.” In some semiconductor packages, such as in a fan out wafer level package (FOWLP) and/or fan-out panel level package (FOPLP), a plurality of semiconductor IC dies may be mounted to an interposer, such as an organic interposer or a semiconductor (e.g., silicon) interposer, that may include interconnect structures extending therethrough. The resulting package structure, including the interposer and the semiconductor IC dies mounted thereon, may then be mounted onto a surface of a package substrate using solder connections.

Many semiconductor packages may include a large number of IC dies integrated in the semiconductor package. The inclusion of the large number of IC dies may induce mechanical stress and the warping of the interposer and/or of the package substrate. As the interposer and/or the package substrate warp, the potential for defective solder connections between these components increases. Such defective solder connections may include, for example, instances of solder cold joints in which insufficient melting of the solder material provides a poor bond that is susceptible to cracking and separation and/or instances of solder bridging in which solder material from one solder ball contacts solder material from a neighboring solder ball, resulting in an unintended connection. In some cases, depending on the warpage of the interposer and/or the package substrate, different types of solder defects may occur in different regions of the semiconductor package.

In order to improve the reliability of the electrical connections within semiconductor packages, various embodiments disclosed herein include semiconductor packages and methods of fabricating semiconductor packages that include a package substrate having an outer coating layer, such as solder resist layer. A plurality of openings through the outer coating layer of the package substrate expose an array of bonding pads used to bond a package structure, including an interposer and at least one semiconductor IC die, to the package substrate. The openings through the outer coating layer of the package substrate may include non-uniform dimensions in different regions of the package substrate. The non-uniform dimensions of the openings through the outer coating layer of the package substrate may mitigate against warpage of the interposer and thereby provide improved bonding connections between the bonding pads of the package substrate and corresponding bonding structures on the interposer of the package structure.

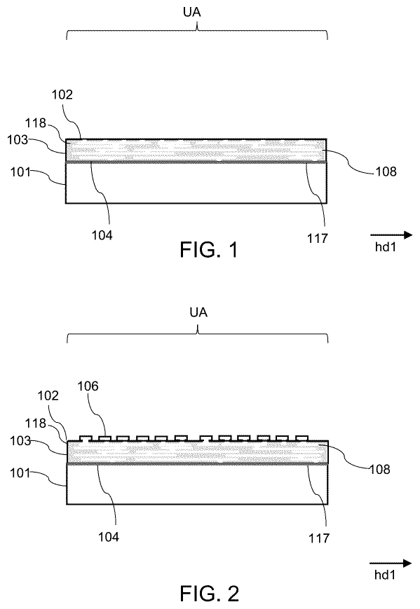

FIG. 1 is a vertical cross-section view of an exemplary intermediate structure during a process of forming a semiconductor package according to various embodiments of the present disclosure. Referring to FIG. 1, the exemplary intermediate structure includes a first carrier substrate 101 and an interposer 103 formed and mounted over a front side surface of the first carrier substrate 101. The first carrier substrate 101 may provide mechanical support to the interposer 103. The first carrier substrate 101 may be formed of a suitable substrate material, such as glass material, a ceramic material (e.g., a sapphire substrate), a semiconductor material (e.g., a silicon substrate), or the like. Other suitable materials for the first carrier substrate 101 are within the contemplated scope of disclosure. In some embodiments, the first carrier substrate 101 may be formed of an optically transparent material.

In some embodiments, a first release layer 117 may be located over the front side surface of the first carrier substrate 101, and the interposer 103 may be located over the first release layer 117. The first release layer 117 may include an adhesive material that may adhere the interposer 103 to the front side surface of the first carrier substrate 101. In some embodiments, the first release layer 117 may include an adhesive material that may be subsequently treated to cause the adhesive material of the first release layer 117 lose its adhesive properties, such that the first carrier substrate 101 may be separated from the interposer 103. In some embodiments, the adhesive material of the first release layer 117 may lose its adhesive properties when subjected to treatment using an energy source, such as a thermal, optical (e.g., UV, laser, etc.) and/or sonic (e.g., ultrasonic) energy source. In one non-limiting example, the first release layer 117 may include a light-to-heat conversion (LTHC) material that may selectively absorb optical radiation in certain wavelength range(s), such as ultraviolet radiation, causing the LTHC material to heat up and thereby lose adhesion. In other embodiments in which the first carrier substrate 101 is formed of an optically transparent material, the application of an optical energy source may cause the first release layer 117 to lose its adhesive property. Alternatively, the first release layer 117 may include an adhesive material, such as an acrylic pressure-sensitive adhesive material, that may decompose when subjected to an elevated temperature. Other suitable materials for the first release layer 117 are within the contemplated scope of disclosure.

Referring again to FIG. 1, the interposer 103 may include a first side surface 102 and a second side surface 104 opposite the first side surface 102. The second side surface 104 of the interposer 103 may face the front side surface of the first carrier substrate 101. A plurality of conductive interconnect structures 108 (e.g., metal lines and vias) may extend within the interposer 103 between the first side surface 102 and the second side surface 104 of the interposer 103. The conductive interconnect structures 108 may be formed in and surrounded by an insulating matrix that may be composed of a dielectric material 118. The conductive interconnect structures 108 of the interposer 103 may be configured to route electrical signals between semiconductor integrated circuit (IC) dies and a package substrate in a semiconductor package to be subsequently formed. Thus, the conductive interconnect structures 108 of the interposer 103 may also be referred to as “redistribution structures.”

In some embodiments, the interposer 103 may be an organic interposer. The organic interposer 103 may be formed on the first carrier substrate 101. In one non-limiting example, the interposer 103 may be formed by sequentially depositing layers of a dielectric material 118, such as a dielectric polymer material, over the front side surface of the first carrier substrate 101 (and over the first release layer 117, in embodiments in which used the first release layer 117). Each of the layers of dielectric material 118 may be lithographically patterned and etched to form open regions (e.g., trenches and/or via openings), and a metallization process may then be used to fill the open regions and form conductive interconnect structures 108 (e.g., metal lines and vias) within each successive layer of dielectric material 118. In this manner, the interposer 103 may be built layer-by-layer over the front side surface of the first carrier substrate 101. Each layer of a dielectric material 118 and corresponding conductive interconnect structures 108 of the interposer 103 may be referred to as a redistribution layer (RDL). In some embodiments, the interposer 103 may include at least four (4) redistribution layers (RDLs).

In some embodiments, each of the layers of dielectric material 118 of the interposer 103 may include a suitable dielectric polymer material, such as polyimide (PI), benzocyclobutene (BCB), or polybenzobisoxazole (PBO). Other suitable dielectric materials are within the contemplated scope of disclosure. The layers of dielectric material 118 of the interposer 103 may be formed using a suitable deposition process, such as a spin coating and drying process. Other suitable deposition processes are within the contemplated scope of disclosure.

The conductive interconnect structures 108 of the interposer 103 may be formed of a suitable conductive material, such as Cu, Ni, W, Co, Mo, Ru, etc., including alloys and combinations of the same. In some embodiments, the conductive interconnect structures 108 may include a metallic barrier layer, such as a layer of Ti, TiN, TaN, or WN, contacting the dielectric material 118, and a metallic fill material, which may include an elemental metal (e.g., Cu, Ni, etc.) or an alloy or a combination thereof. Other suitable materials for the conductive interconnect structures 108 of the interposer 103 are within the contemplated scope of disclosure. The conductive interconnect structures 108 of the interposer 103 may be formed using any suitable deposition process. For example, suitable deposition processes may include physical vapor deposition (PVD), sputtering, chemical vapor deposition (CVD), atomic layer deposition (ALD), plasma-enhanced chemical vapor deposition (PECVD), electrochemical deposition (e.g., electroplating), or combinations thereof.

Referring again to FIG. 1, an instance of an interposer 103 located over the front side surface of the first carrier substrate 101 may be referred to as a unit area (UA) of the first carrier substrate 101. A single unit area (UA) is illustrated in FIG. 1, although it will be understood that the first carrier substrate 101 may include a plurality of unit areas (UAs), where each unit area (UA) may include a separate instance of an interposer 103 over the front side surface of the first carrier substrate 101. For example, the first carrier substrate 101 may include a periodic two-dimensional array (such as a rectangular array) of unit areas (UAs), where each unit area (UA) of the array may include a separate instance of an interposer 103 over the front side surface of the carrier substrate 101. In some embodiments, each interposer 103 within a unit area (UA) of the array may have an identical structure. The plurality of interposers 103 over the first carrier substrate 101 may be continuous with one another, such that a continuous layer of dielectric material 118 may extend over the front side surface of the first carrier substrate 101, with separate instances of conductive interconnect structures 108 formed within the continuous layer of dielectric material 118 in each unit area (UA).

FIG. 2 is a vertical cross-section view of the exemplary intermediate structure showing interposer bonding structures 106 located over the first side surface 102 of the interposer 103 according to various embodiments of the present disclosure. Referring to FIG. 2, the interposer bonding structures 106 may include a plurality of metallic bumps. The interposer bonding structures 106 may be formed by depositing one or more layers of a metal material and patterning the one or more layers of metal material to form the plurality of interposer bonding structures 106 over the first side surface 102 of the interposer 103. Each bonding structure 106 may be electrically coupled to an underlying conductive interconnect structure 108 of the interposer 103. In some embodiments, the interposer bonding structures 106 may form at least one periodic two-dimensional array (such as a rectangular array) of interposer bonding structures 106 within the unit area (UA). In some embodiments, a plurality of interposer bonding structures 106 may be formed over the first side surface 102 of the interposer 103 in each unit area (UA) of the first carrier substrate 101.

In various embodiments, the interposer bonding structures 106 may be configured for subsequent microbump bonding (i.e., C2 bonding) to corresponding bonding structures formed on semiconductor integrated circuit (IC) dies. In some embodiments, the interposer bonding structures 106 may include a plurality of metal pillars. The metal pillars may include copper or a copper-containing alloy. In some embodiments, the bonding structures may include a plurality of metal stacks, such as a plurality of Cu—Ni—Cu stacks. In some embodiments, the interposer bonding structures 106 may include a solder material, such as tin or a tin-containing alloy, on an upper surface of the interposer bonding structures 106. Other suitable materials and/or configurations for the interposer bonding structures 106 are within the contemplated scope of disclosure.

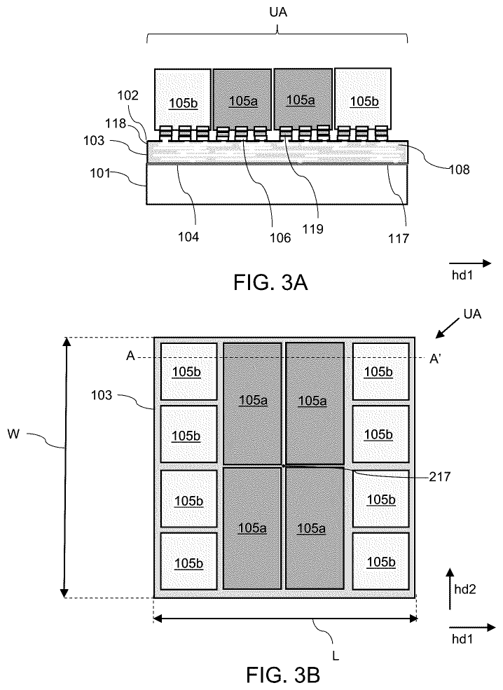

FIG. 3A is a vertical cross-section view of the exemplary intermediate structure showing a plurality of semiconductor integrated circuit (IC) dies 105a, 105b mounted over the first side surface 102 of the interposer 103 according to various embodiments of the present disclosure. FIG. 3B is a top view of the exemplary intermediate structure shown in FIG. 3A. The vertical cross-section view of FIG. 3A is taken along line A-A′ in FIG. 3B. Referring to FIGS. 3A and 3B, in some embodiments, the plurality of IC semiconductor dies 105a, 105b may include at least one system-on-chip (SoC) die 105a. An SoC die 105a may include, for example, an application specific integrated circuit (ASIC) die, a central processing unit die, and/or a graphic processing unit die. In some embodiments, the plurality of IC semiconductor dies 105a, 105b may include at least one memory die 105b. The at least one memory die 105b may include a high bandwidth memory (HBM) die. In some embodiments, a HBM die may include a vertical stack of interconnected memory dies. Alternatively, or in addition, the at least one memory die 105b may include a dynamic random access memory (DRAM) die. In some embodiments, the plurality of semiconductor IC dies 105a, 105b may be homogeneous, meaning that all of the semiconductor IC dies 105a, 105b may be of the same type (e.g., all SoC dies, all HBM dies, all DRAM dies, etc.). Alternatively, the plurality of semiconductor IC dies 105a, 105b may be heterogeneous, meaning that the plurality of semiconductor IC dies 105a, 105b may include different types of semiconductor IC dies 105a, 105b (e.g., at least one SoC die and at least one memory die).

In some embodiments, the plurality of semiconductor IC dies 105a, 105b may include one or more SoC dies 105a and a plurality of memory dies 105b. The one or more SoC dies 105a may be located in a central portion of the unit area (UA) and the plurality of memory dies 105b may laterally surround the one or more SoC dies 105a. FIGS. 3A and 3B illustrate an embodiment including four SoC dies 105a and eight memory dies 105b (e.g., HBM dies). The four SoC dies 105a may be located in the central portion of the unit area (UA) and arranged in two rows of two SoC dies 105a each, where the rows of SoC dies 105a are adjacent to one another along a first horizontal direction hd1 and extend along a second horizontal direction hd2. The eight memory dies 105b are arranged in two rows of four memory dies 105b each that extend along the second horizontal direction hd2 on either side of the rows of SoC dies 105a. Other suitable layouts for the semiconductor IC dies 105a, 105b are within the contemplated scope of disclosure.

Referring again to FIG. 3A, each of the semiconductor IC dies 105a, 105b may include a plurality of semiconductor die bonding structures 119 located over a lower surface of the semiconductor IC die 105a, 105b. The semiconductor die bonding structures 119 on the semiconductor IC dies 105a, 105b may have a similar or identical configuration as the interposer bonding structures 106 over the first side surface 102 of the interposer 103 described above with reference to FIG. 2. For example, the semiconductor die bonding structures 119 on the lower surfaces of the semiconductor IC dies 105a, 105b may include a plurality of metallic bumps, such as metal pillars and/or metal stacks. In some embodiments, the semiconductor die bonding structures 119 on the semiconductor IC dies 105a, 105b may include a solder material, such as tin or a tin-containing alloy, on the lower surface of the semiconductor die bonding structures 119. The semiconductor die bonding structures 119 on the lower surfaces of each semiconductor IC die 105a, 105b may be configured for microbump bonding (i.e., C2 bonding) to corresponding interposer bonding structures 106 on the first side surface 102 of the interposer 103.

The semiconductor IC dies 105a, 105b (collectively semiconductor IC dies 105) may be mounted over the first side surface 102 of the interposer 103 by placing each of the semiconductor IC dies 105 over the first side surface 102 of the interposer 103 (e.g., using a pick-and-place apparatus). The semiconductor IC dies 105a, 105b may be aligned over the first side surface 102 of the interposer 103 such that the semiconductor die bonding structures 119 on the lower surfaces of the semiconductor IC dies 105 contact corresponding interposer bonding structures 106 over the first side surface 102 of the interposer 103. A reflow process may be used to bond the semiconductor die bonding structures 119 on the lower surfaces of the semiconductor IC dies 105a, 105b to the corresponding interposer bonding structures 106 over the first side surface 102 of the interposer 103, thereby providing a mechanical and electrical connection between each of the semiconductor IC dies 105a, 105b and the interposer 103. In various embodiments, a plurality of semiconductor IC dies 105a, 105b may be mounted over the first side surface 102 of the interposer 103 within each unit area (UA) of the first carrier substrate 101.

Referring again to FIG. 3B, each unit area (UA) of the first carrier substrate 101 including a set of semiconductor IC dies 105a, 105b mounted to the interposer 103 may have a length dimension, L, along the first horizontal direction hd1 and a width dimension, W, along the second horizontal direction hd2. The point labeled 217 indicates the geometric center 217 of the unit area (UA).

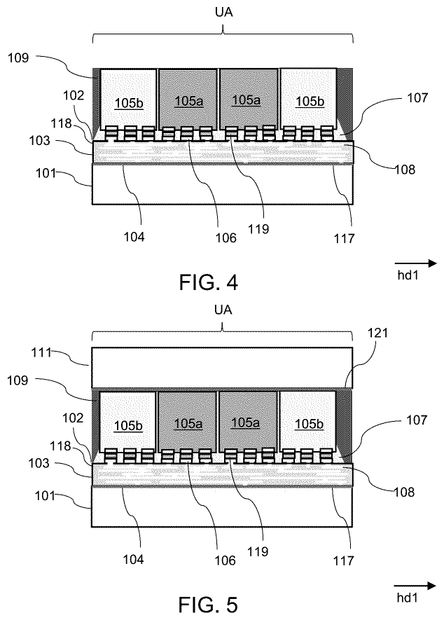

FIG. 4 is a vertical cross-section view of the exemplary intermediate structure showing a first underfill material portion 107 located between the lower surfaces of the semiconductor IC dies 105a, 105b and the first side surface 102 of the interposer 103, and a molding portion 109 around the outer periphery of the plurality of semiconductor IC dies 105a, 105b according to various embodiments of the present disclosure. Referring to FIG. 4, the first underfill material portion 107 may be applied into the spaces between the first side surface 102 of the interposer 103 and the plurality of semiconductor IC dies 105a, 105b mounted to the interposer 103. The first underfill material portion 107 may laterally surround and contact each of the interposer bonding structures 106 and semiconductor die bonding structures 119 that bond the respective semiconductor IC dies 105 to the interposer 103. The first underfill material portion 107 may also be located between adjacent semiconductor IC dies 105a, 105b of the plurality of semiconductor IC dies 105a, 105b mounted to the interposer 103.

The first underfill material portion 107 may include any underfill material known in the art. For example, the first underfill material portion 107 may be composed of an epoxy-based material, which may include a composite of resin and filler materials. Other suitable materials for the first underfill material portion 107 are within the contemplated scope of disclosure. Any known underfill material application method may be used to apply the first underfill material portion 107.

Referring again to FIG. 4, a molding portion 109 may laterally surround the plurality of semiconductor IC dies 105a, 105b mounted to the interposer 103. The molding portion 109 may contact lateral side surfaces of at least some of the semiconductor IC dies 105a, 105b and may also contact the first underfill material portion 107. In various embodiments, the molding portion 109 may include an epoxy material. For example, the molding portion 109 may include an epoxy mold compound (EMC) that may include epoxy resin, a hardener (i.e., a curing agent), silica or other filler material(s), and optionally additional additives. The EMC may be applied around the periphery of the semiconductor IC dies 105a, 105b in liquid or solid form, and may be hardened (i.e., cured) to form a molding portion 109 having sufficient stiffness and mechanical strength surrounding the plurality of semiconductor IC dies 105a, 105b. Portions of the molding portion 109 that extend above a horizontal plane including the top surfaces of the semiconductor IC dies 105a, 105b may be removed using a planarization process, such as a chemical mechanical planarization (CMP) process.

In various embodiments, each unit area (UA) of the first carrier substrate 101 may include a first underfill material portion 107 located between the first side surface 102 of the interposer 103 and the undersides of the plurality of semiconductor IC dies 105a, 105b mounted to the interposer 103, and a molding portion 109 around the outer periphery of the plurality of semiconductor IC dies 105a, 105b. In some embodiments, the molding portion 109 may form a continuous matrix extending between the unit areas (UAs) of the first carrier substrate 101 and laterally surrounding and embedding the respective sets of semiconductor IC dies 105a, 105b within each of the unit areas (UAs) of the first carrier substrate 101.

FIG. 5 is a vertical cross-section view of the exemplary intermediate structure showing a second release layer 121 located over the upper surfaces of the plurality of semiconductor dies 105a, 105b, the exposed upper surface of the first underfill material portion 107 and the exposed upper surface of the molding portion 109, and a second carrier substrate 111 over the second release layer 121 according to various embodiments of the present disclosure. Referring to FIG. 5, the second release layer 121 may include an adhesive material that may adhere the second carrier substrate 111 to the upper surfaces of the plurality of semiconductor dies 105a, 105b, the first underfill material portion 107 and the molding portion 109. As with the first release layer 117 described above, the second release layer 121 may also be configured to lose its adhesive properties when subjected to a treatment using an energy source, such as a thermal, optical (e.g., UV, laser, etc.) and/or sonic (e.g., ultrasonic) energy source. In some embodiments, the first release layer 117 and the second release layer 121 may be composed of the same material(s). Alternatively, the first release layer 117 and the second release layer 121 may be composed of different material(s).

Referring again to FIG. 5, the second carrier substrate 111 may be formed of a suitable substrate material, such as the materials described above with reference to the first carrier substrate 101 shown in FIG. 1. In some embodiments, the second carrier substrate 111 may be composed of the same material(s) as the first carrier substrate 101. Alternatively, the second carrier substrate 111 and the first carrier substrate 101 may be composed of different material(s). In various embodiments, the second carrier substrate 111 may extend over each of the unit areas (UAs) of the first carrier substrate 101 such that each unit area (UA) of the first carrier substrate 101 may correspond to an equivalent unit area (UA) of the second carrier substrate 111.

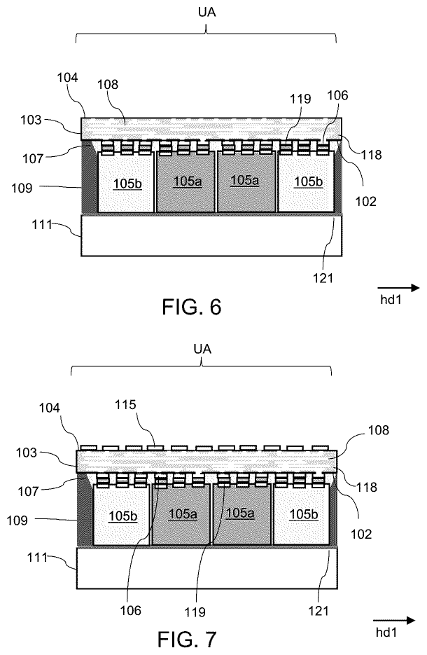

FIG. 6 is a vertical cross-section view of the exemplary intermediate structure showing the first carrier substrate 101 removed according to various embodiments of the present disclosure. Referring to FIG. 6, the first carrier substrate 101 may be removed using any suitable method known in the art. In embodiments in which the first carrier substrate 101 is adhered to the interposer 103 by a first release layer 117, the first release layer 117 may be subjected to a treatment that causes the first release layer 117 to lose its adhesive properties. This may enable the first carrier substrate 101 to be separated from the exemplary intermediate structure. For example, the first release layer 117 may include a light-to-heat conversion (LTHC) material that may be irradiated by optical radiation in a specified wavelength range, such as ultraviolet radiation, causing the LTHC material to heat up and thereby lose adhesion. The first release layer 117 may optionally be irradiated through the first carrier substrate 101 in embodiments in which the first carrier substrate 101 is composed of an optically-transparent material. Alternatively, the first release layer 117 may include a thermally-decomposing adhesive material. The exemplary intermediate structure be subjected to a thermal anneal process at a debonding temperature sufficient to cause the first release layer 117 to decompose and thereby enable the first carrier substrate 101 to be detached from the exemplary intermediate structure. In embodiments in which a thermal anneal process is used to remove the first carrier substrate 101, the debonding temperature used to thermally decompose the first release layer 117 may not be sufficient cause the second release layer 121 to lose its adhesive properties.

Referring again to FIG. 6, the exemplary intermediate structure may be inverted (i.e., flipped over), either prior to or following the removal of the first carrier substrate 101, such that the interposer 103 may be located over and supported by the second carrier substrate 111.

FIG. 7 is a vertical cross-section view of the exemplary intermediate structure showing a plurality of bonding structures 115 located over the second side surface 104 of the interposer 103 according to various embodiments of the present disclosure. Referring to FIG. 7, the bonding structures 115 may be formed of a suitable metallic material, such as copper, aluminum, nickel, titanium, etc., including combinations and alloys thereof. Other suitable metallic materials for the bonding structures 115 are within the contemplated scope of disclosure. The bonding structures 115 may be a single layer structure, or may be a multi-layer structure composed of multiple layers of different metallic materials. Each of the bonding structures 115 may be electrically coupled to an underlying conductive interconnect structure 108 of the interposer 103. In some embodiments, the bonding structures 115 may include disc-or pad-shaped structures. Other suitable structures, such as pillar-shaped structures, may also be utilized. In some embodiments, the bonding structures 115 may have a circular horizontal cross-sectional shape. Other suitable horizontal cross-sectional shapes of the bonding structures 115, such as polygonal (e.g., rectangular or square), elliptical, and/or irregular shapes, are within the contemplated scope of disclosure. In some embodiments, the plurality of bonding structures 115 may form a periodic two-dimensional array (such as a rectangular array) of bonding structures 115 within the unit area (UA).

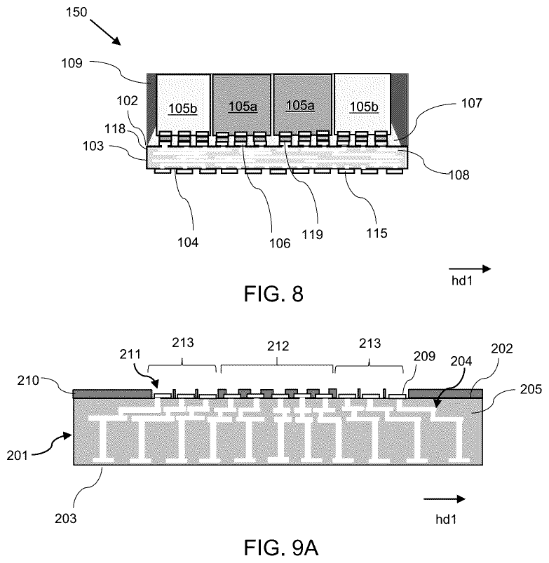

FIG. 8 is a vertical cross-section view of an exemplary intermediate structure showing a package structure 150 according to various embodiments of the present disclosure. Referring to FIG. 8, the second carrier substrate 111 may be removed from the exemplary intermediate package structure 150 shown in FIG. 7. The second carrier substrate 111 may be removed using any suitable method known in the art, such as any of the methods described above for removal of the first carrier substrate 101. In embodiments in which the second carrier substrate 111 is adhered to the semiconductor IC dies 105a, 105b, the first underfill material portion 107 and the molding portion 109 using a second release layer 121, the second release layer 121 may be subjected to a treatment that causes the second release layer 121 to lose its adhesive properties, such as a thermal anneal and/or an optical irradiation treatment process as described above with reference to FIG. 6. The package structure 150 may be inverted (i.e., flipped over) relative to the orientation shown in FIG. 7.

A dicing process may be used to separate each unit area (UA) of the exemplary intermediate structure to provide a plurality of discrete package structures 150. Each package structure 150 may include an interposer 103, a plurality of semiconductor IC dies 105a, 105b mounted over a first side surface 102 of the interposer 103, a first underfill material portion 107 located in the gaps between the first side surface 102 of the interposer 103 and each of the semiconductor IC dies 105, and a molding portion 109 laterally surrounding the plurality of semiconductor IC dies 105. A plurality of bonding structures 115 may be located on the second side surface 104 of the interposer 103. Each package structure 150 may include a length dimension, L, along a first horizontal direction hd1 and a width dimension, W, along a second horizontal direction hd2 equivalent to length and width dimensions of the respective unit areas (UAs) as described above with reference to FIG. 3B.

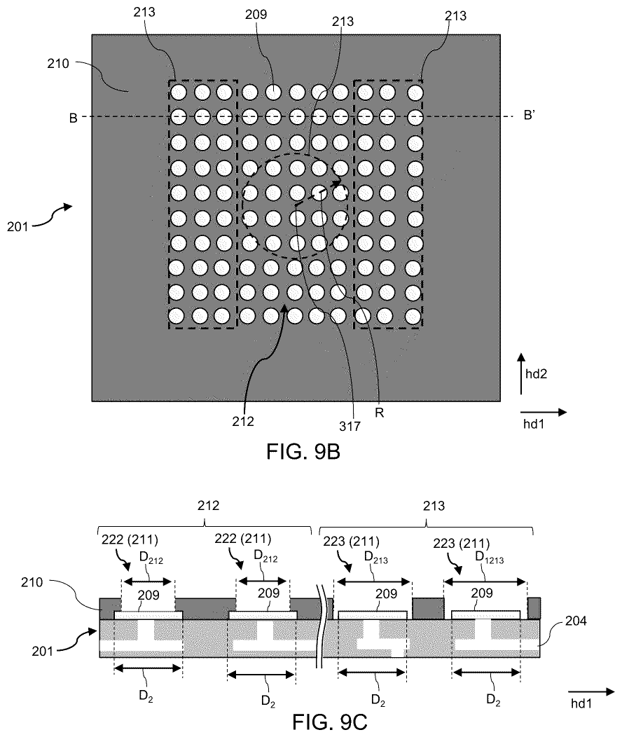

FIG. 9A is a vertical cross-section view of a package substrate 201 according to various embodiments of the present disclosure. FIG. 9B is a top view of the package substrate 201 of FIG. 9A. The vertical cross-section view of FIG. 9A is taken along line B-B′ in FIG. 9A. FIG. 9C is an enlarged vertical cross-section view of a portion of the package substrate 201 of FIGS. 9A and 9B. Referring to FIGS. 9A-9C, the package substrate 201 may include a first side surface 202 (which, for convenience, may also be referred to as a “front” side surface 202 of the package substrate 201) and a second side surface 203 (which, for convenience, may also be referred to as a “rear” side surface 203 of the package substrate) that is opposite the first side surface 202. In various embodiments described in further detail below, a package structure 150 as shown in FIG. 8 may be mounted to the first (i.e., front) side surface 202 of the package substrate 150 to form a semiconductor package.

In various embodiments, the package substrate 201 may include a dielectric material matrix 205 with conductive interconnect features 204 (e.g., metal lines, vias, etc.) extending within and through the dielectric material matrix 205. In some embodiments, the package substrate 201 may include a solid substrate core with conductive interconnect features 204 (e.g., vias) extending through the substrate core. In one exemplary embodiment, the substrate core may be composed of a sheet of laminate reinforced resin. Redistribution structures may be formed over the front and rear surfaces of the substrate core. The redistribution structures may include layers of a polymer-based dielectric material, such as Ajinomoto Buildup Film (ABF)® product from Ajinomoto Co., Inc., Tokyo, JP, having conductive interconnect features 204 (e.g., metal lines and vias) formed within the layers of dielectric material. Other suitable materials and/or configurations for the package substrate 201 are within the contemplated scope of disclosure.

A plurality of bonding pads 209 may be located on the first (front) side surface 202 of the package substrate 201. Each of the bonding pads 209 may be electrically connected to underlying conductive interconnect features 204 of the package substrate 201. The plurality of bonding pads 209 may be configured to electrically connect the package substrate 201 to corresponding bonding structures 115 (e.g., bonding pads) on the second side surface 104 of an interposer 103 of an above-described package structure 150. The plurality of bonding pads 209 on the front side surface 202 of the package substrate 201 may form a periodic two-dimensional array (such as a rectangular array) of bonding pads 209, where the layout and periodicity of the array of bonding pads 209 on the front side surface 202 of the package substrate 201 may correspond to the layout and periodicity of the bonding structures 115 on the second side surface 104 of the interposer 103. In some embodiments, a similar array of bonding pads may be located over the back side surface 203 of the package substrate 201.

Referring again to FIGS. 9A-9C, the package substrate 201 may further include an outer coating layer 210 on the front side surface 202 of the package substrate 201. The outer coating layer 210 may provide a protective coating for the package substrate 201. The outer coating layer 210 may also inhibit solder material from adhering to the front side surface 202 of the package substrate 201 during a subsequent solder reflow process. In some embodiments, a similar outer coating layer 210 may be located over the back side surface 203 of the package substrate 201.

In various embodiments, the outer coating layer 210 may include a solder resist material. The outer coating layer 210 formed of solder resist material may also be referred to as a “solder mask.” The solder resist material of the outer coating layer 210 may include a suitable resin material that is resistant to humidity and high-temperature, and to which a solder material will not strongly adhere. The solder resist material of the outer coating layer 210 may be formed using a suitable deposition process, such as via screen printing, spraying, and/or vacuum lamination. Other suitable deposition processes are within the contemplated scope of disclosure. Portions of the outer coating layer 210 may be selectively removed (e.g., via an etching process) to form first openings 222 and second openings 223 in the outer coating layer 210 that may expose the underlying bonding pads 209 on the front side surface 202 of the package substrate 201.

As mentioned above, and as discussed more fully below, a package structure 150 as shown in FIG. 8 may be mounted over the front side surface 202 of the package substrate 201 as shown in FIGS. 9A-9C to provide a semiconductor package. In various embodiments, bonding material portions (e.g., solder balls) may be provided between the bonding pads 209 on the front side surface 202 of the package substrate 201 and corresponding bonding structures 115 on the second side surface 104 of the interposer 103. A reflow process at an elevated temperature may be used to form bonding connections between the bonding pads 209 and the corresponding bonding structures 115 and thereby bond the package structure 150 to the package substrate 201.

In some cases, mechanical stress on the package structure 150, including thermal-induced stress resulting from high temperature processing steps, may cause warpage in the package structure 150, including warpage of the interposer 103 to which the semiconductor IC dies 105a, 105b are attached. This warpage may affect the integrity of the bonding connections between bonding pads 209 of the package substrate 201 and the corresponding bonding structures 115 on the second side surface 104 of the interposer 103. In the case of a package structure 150 as shown in FIG. 8, for example, a central region of the interposer 103 underlying the center of the SoC dies 105a and peripheral regions of the interposer 103 underlying the memory dies 105b may have a tendency to “bow” downwards (i.e., towards the front side surface 202 of the semiconductor substrate 201), while other regions of the interposer 103 may have a tendency to “bow” upwards (i.e., away from the front side of surface 202 of the semiconductor substrate 201. Such a warpage of the interposer 103 may increase the risk of “bridging” defects (i.e., where neighboring bonding connections between the interposer 103 and the package substrate 201 may become electrically shorted to each other) occurring in the central region and in the peripheral regions of the semiconductor package where the interposer “bows” downwards. At the same time, there may be an increased risk of “cold joint” defects (i.e., where insufficient melting of the solder material provides poor bonding connections that are susceptible to cracking and separation) occurring in other regions of the semiconductor package where the interposer “bows” upwards.

Various embodiments may include a package substrate 201 including first openings 222 and second openings 223 (collectively openings 211) through an outer coating layer 210 having non-uniform dimensions in different regions of the package substrate 201. As discussed above, first openings 222 and second openings 223 through an outer coating layer 210 (e.g., solder resist layer) on the front side surface 202 of the package substrate 201 may expose the bonding pads 209 used to bond the package substrate 201 to a package structure 150. In various embodiments, the first openings 222 and the second openings 223 that expose the bonding pads 209 may have different sizes in different regions of the package substrate 201. The different sizes of the first openings 222 and the second openings 223 may help to impart different shapes to the bonding material portions (e.g., solder balls) used to mechanically and electrically couple the bonding pads 209 on the package substrate 201 to the corresponding bonding structures 115 on the package structure 150. The different shapes of the bonding material portions may mitigate against warpage of the interposer 103 of the package structure 150 and reduce the risk of bonding defects (e.g., bridging defects and/or cold joint defects) occurring in different regions of the semiconductor package.

Referring again to FIGS. 9A-9C, the package substrate 201 may include at least one first region 212 and at least one second region 213. The package substrate 201 may include a plurality of bonding pads 209 exposed through the first openings 222 and the second openings 223 in an outer coating layer 210 on a front side surface 202 of the package substrate 201, where the first openings 222 and the second openings 223 may include width dimension, D₂₁₂ and D₂₁₃, respectively, as shown in the enlarged vertical cross-section view of FIG. 9C. In various embodiments, the first width dimension, D₂₁₂, of the first openings 222 located in the at least one first region 212 of the package substrate 201 may be less than the second width dimension, D₂₁₃, of the second openings 223 in the at least one second region 213 of the package substrate 201.

In the embodiment of FIG. 9A-9C, the first openings 222 and the second openings 223 through the outer coating layer 201 have a circular cross-sectional shape, such that the first width dimension D₂₁₂ of the first opening 222 and second width dimension D₂₁₃ of the second opening 223 each corresponds to the diameter of the respective first opening 222 and second opening 223. It will be understood that the first openings 222 and the second openings 223 (collectively opening 211) may have different cross-sectional shapes, such as a polygonal, elliptical, or an irregular shape. In such cases, the first width dimension D₂₁₂ of the first opening 222 and the second width dimension D₂₁₃ of the second openings 223 may be different along different horizontal directions (e.g., hd1 and hd2). In various embodiments, at least one first width dimension, D₂₁₂, of the first openings 222 located in the at least one first region 212 may be less than the corresponding second width dimension, D₂₁₃, of the second openings 223 in the at least one second region 213 along the same horizontal direction. In various embodiments, a cross-sectional area of the first openings 222 in the at least one first region 212 may be less than the cross-sectional area of the second openings 223 in the at one second region 213.

Referring to FIGS. 9A and 9B, in some embodiments, the package substrate 201 may include a second region 213 located in the central region of the array of bonding pads 209 on the package substrate 201. In the assembled semiconductor package, the second region 213 located in the central region of the array of bonding pads 209 on the package substrate 201 may underlie one or more SoC dies 105a in a central portion of the package structure 150. Referring to FIG. 9B, the point labeled 317 may underlie the geometric center 217 of the package structure 150 in the assembled semiconductor package. In some embodiments, the second region 213 in the central region of the package substrate 201 may be circumscribed by a circle centered on point 317 and having a radius, R. In various embodiments, R may be ≤70% of the above-described length, L, and/or width, W, dimensions of the package structure 150 (see FIG. 3B).

Alternatively, or in addition, the package substrate 201 may include second region(s) 213 in one or more peripheral regions of the array of bonding pads 209 on the package substrate 201. Referring again to FIGS. 9A and 9B, a pair of second regions 213 is shown extending along opposite peripheral edges of the array of bonding pads 209 on the package substrate 201. In the assembled semiconductor package, the second regions 213 located in the periphery of the array of bonding pads 209 may underlie the plurality of memory dies 105b located on the periphery of the package structure 150. The pair of second regions 213 in the periphery of the array of bonding pads 209 in the embodiment of FIG. 9B extend in the second horizontal direction hd2 along the entire peripheral edges of the array of bonding pads 209.

In some embodiments, the bonding pads 209 in the at least one first region 212 of the package substrate 201 may be solder mask defined (SMD) bonding pads 209, and the bonding pads 209 in the at least one second region 213 of the package substrate 201 may be non-solder mask defined (NSMD) bonding pads 209. Referring to the enlarged vertical cross-section view of the package substrate 201 shown in FIG. 9C, each of the bonding pads 209 may have a total bonding pad width dimension, D₂. In the first region 212 of the package substrate 201 shown on the left-hand side of FIG. 9C, the bonding pads 209 are solder mask defined (SMD) pads, meaning that the portion of each of the bonding pad 209 that is exposed through the outer coating (e.g., solder resist) layer 210 is smaller than the total bonding pad width, D₂, of the bonding pad 209. In other words, the outer coating layer 210 contacts and extends partially over the upper surface of each of the bonding pads 209. Accordingly, the first width dimension, D₂₁₂, of each of the first openings 222 in the outer coating layer 210 is less than the total bonding pad width dimension, D₂, of the bonding pad 209 exposed through the first opening 222.

In contrast, in the second region 213 of the package substrate 201 shown on the right-hand side of FIG. 9C, the bonding pads 209 are non-solder mask defined (NSMD) pads, meaning that the bonding pads 209 are exposed through the outer coating (e.g., solder resist) layer 210 over the total bonding pad width, D₂, of the bonding pads 209. In other words, the outer coating layer 210 does not contact the side surfaces or the upper surfaces of the bonding pads 209. Accordingly, the second width dimension, D₂₁₃, of each of the second openings 223 in the outer coating layer 210 is greater than the total bonding pad width dimension, D₂, of the bonding pad 209 exposed through the second opening 223.

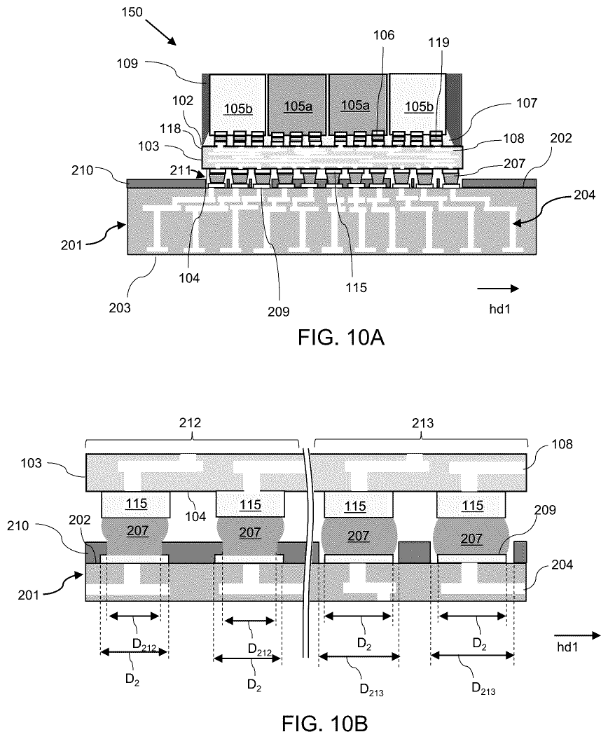

FIG. 10A is a vertical cross-section view of an exemplary intermediate structure during a process of forming a semiconductor package showing a package structure 150 mounted over the front side surface 202 of a package substrate 201 according to various embodiments of the present disclosure. FIG. 10B is an enlarged vertical cross-section view of a portion of the exemplary intermediate structure of FIG. 10A. Referring to FIGS. 10A and 10B, a package structure 150 as described above with reference to FIG. 8 may be aligned over a package substrate 201 as described above with reference to FIGS. 9A-9C such that the second side surface 104 of the interposer 103 of the package structure 150 faces the front side surface 202 of the package substrate 201. The package structure 150 may be disposed over the front side surface 202 of the package substrate 201 such that an array of bonding material portions 207 (e.g., solder balls) are located between the bonding pads 209 exposed through the openings 211 in the outer coating layer 210 on the front side surface 202 of the package substrate 201 and the corresponding bonding structures 115 over the second side surface 104 of the interposer 103.

A reflow process may be performed to reflow the bonding material portions 207, thereby inducing bonding between the interposer 103 of the package structure 150 and the package substrate 201. The reflow process may be performed at an elevated temperature, such as between 150° C. and 350° C. (e.g., ˜250° C.). Following the reflow process, each of the bonding material portions 207 (e.g., solder material portions) may be bonded to a respective one of bonding structures 115 over the second side surface 104 of the interposer 103 and to a respective one of the bonding pads 209 on the front side surface 202 of the package substrate 201. In some embodiments, the bonding material portions 207 may include C4 solder balls, and the package structure 150 may be bonded to the substrate package 201 through an array of C4 solder balls.

Referring to FIG. 10B, the variations in the first width dimensions D₂₁₂ of the first openings 222 and second width dimensions D₂₁₃ of the second openings 223 in the outer coating layer 210 between the first region(s) 212 and the second region(s) 213, respectively, of the package substrate 201 may help to mitigate against the warping of the interposer 103 of the package structure 150. In particular, in cases where the portions of the interposer 103 overlying the second region(s) 213 tend to “bow” downwards towards the upper surface 202 of the package substrate 201, the relatively larger second width dimensions, D₂₁₃, of the second openings 223 may provide an increased contact area between the bonding material portions 207 and the bonding pads 209, including along the side surfaces of the bonding pads 209, as well as an increased volume within each of the second openings 223 into which the bonding material portions 207 may flow. This may inhibit the bonding material portions 207 from flowing over the upper surface of the outer coating layer 210, thereby decreasing the risk of “bridging” defects occurring between neighboring bonding connections. Similarly, the relatively smaller first width dimensions D₂₁₂, of the first openings 222 in the first region(s) 212 of the package substrate 201 may impart a pillar-like shape to the bonding material portions 207 that may help to maintain the integrity of the bonding connections in instances in which the portions of the interposer 103 overlying the first regions(s) 212 tend to “bow” upwards away from the upper surface 202 of the package substrate 201. Accordingly, the risk of “cold joint” defects may be reduced.

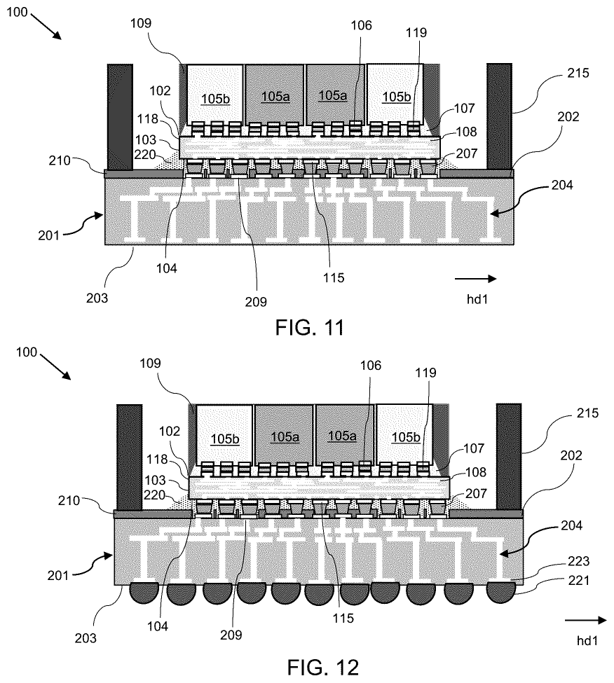

FIG. 11 is a vertical cross-section view of a semiconductor package 100 including a second underfill material portion 220 located between the front side surface 202 of the package substrate 201 and the second side surface 104 of the interposer 103 according to various embodiments of the present disclosure. Referring to FIG. 11, the second underfill material portion 220 may be applied into the space between the front side surface 202 of the package substrate 201 and the second side surface 104 of the interposer 103. The second underfill material portion 220 may laterally surround and contact each of the bonding material portions 207 that bond the interposer 103 to the package substrate 201.

The second underfill material portion 220 may include any underfill material known in the art. For example, the second underfill material portion 220 may be composed of an epoxy-based material, which may include a composite of resin and filler materials. Other suitable materials for the second underfill material portion 220 are within the contemplated scope of disclosure. Any known underfill material application method may be used to apply the second underfill material portion 220. An optional stiffening member 215, such as a ring structure and/or a lid structure may be mounted to the first side surface 202 of the package substrate 201 and may laterally surround the package structure 150 as shown in FIG. 11.

FIG. 12 is a vertical cross-section view of the semiconductor package 100 including a plurality of solder balls 221 located on the rear side surface 203 of the package substrate 201. Each of the solder balls 221 may contact bonding pads 223 exposed through the rear side surface 203 of the package substrate 201. The solder balls 221 may be used to mount the rear side surface 203 of the semiconductor package 100 onto a support substrate containing electrical interconnects, such as a printed circuit board (PCB). In some embodiments, the solder balls 221 may include a ball grid array (BGA), and the semiconductor package 100 may be mounted to the support substrate via a BGA connection.

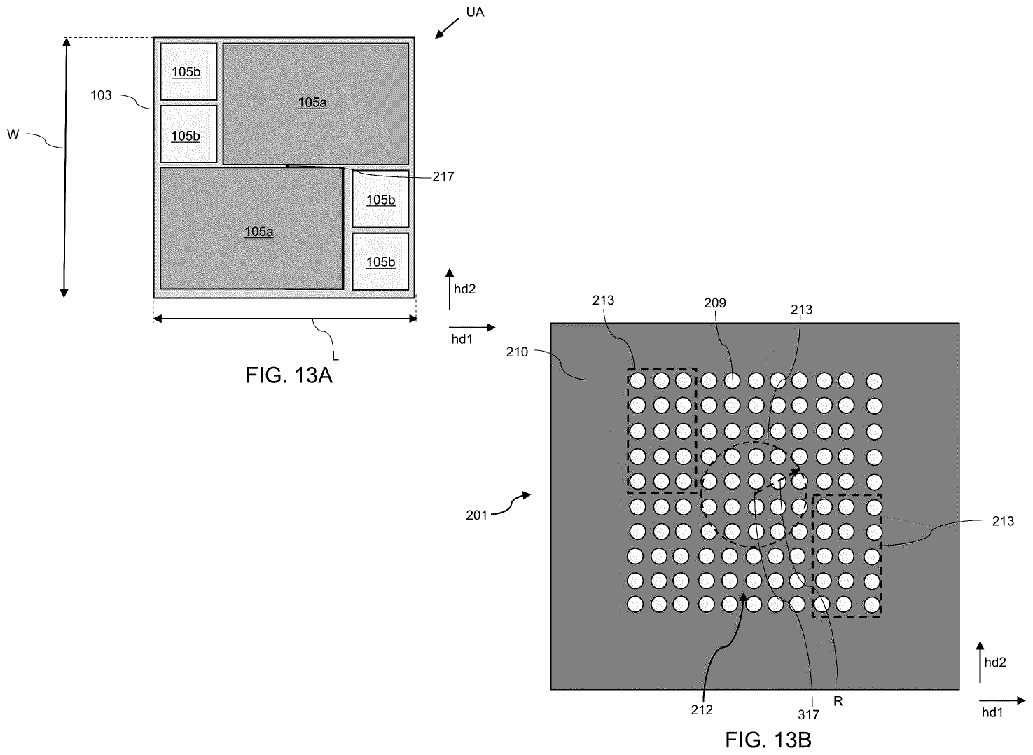

FIG. 13A is a top view of an exemplary intermediate structure illustrating an alternative layout of the plurality of semiconductor IC dies 105a, 105b in a unit area (UA) according to an embodiment of the present disclosure. FIG. 13B is a top view of a package substrate 201 to which a package substrate 150 having a layout of semiconductor integrated circuit (IC) dies 105a, 105b as shown in FIG. 13A may be mounted to form a semiconductor package according to an embodiment of the present disclosure. The exemplary intermediate structure shown in FIG. 13A may be similar to the exemplary intermediate structure described above with reference to FIG. 3B. Thus, repeated discussion of like features is omitted for brevity. The exemplary intermediate structure shown in FIG. 13A may differ from the exemplary intermediate structure of FIG. 3B with respect to the layout of the semiconductor IC dies 105a, 105b. In particular, the exemplary intermediate structure of FIG. 13A includes two SoC dies 105a and four memory dies 105b. The two SoC dies 105a are offset from one another along the first horizontal direction hd1 such that a first SoC die 105a is located in the lower left-hand corner of the unit area (UA) and extends along the lower periphery of the unit area (UA) along the first horizontal direction hd1, while the second SoC die 105a is located in the upper right-hand corner of the unit area (UA) and extends along the upper periphery of the unit area (UA) along the first horizontal direction hd1. The first SoC die 105a and the second SoC die 105b may be adjacent to one another in a central region of the unit area (UA). A first pair of memory dies 105b are located in the upper left-hand corner of the unit area (UA) above the first SoC die 105a and laterally adjacent to the second SoC die 105a. A second pair of memory dies 105b are located in the lower right-hand corner of the unit area (UA) below the second SoC die 105a and laterally adjacent to the first SoC die 105a. The point labeled 217 indicates the geometric center 217 of the unit area (UA). In various embodiments, the processing operations described above with respect to FIGS. 4-8 may be performed to provide a package structure 150 having a layout of semiconductor IC dies 105a, 105b as shown in FIG. 13A.

Referring to FIG. 13B, the package substrate 201 shown in FIG. 13B may be similar to the package substrate 201 described above with reference to FIGS. 9A-9C. As in the embodiment of FIGS. 9A-9C, the package substrate 201 may include at least one first region 212 and at least one second region 213, where the first width dimensions, D₂₁₂ of the first openings 222 through the outer coating layer 210 that expose the bonding pads 209 in the at least one first region 212 may be less than the second width dimensions D₂₁₃ of the second openings 223 through the outer coating layer 210 that expose the bonding pads 209 in the at least one second region 213. The package substrate 201 of FIG. 13B may differ from the package substrate 201 of FIGS. 9A-9C with respect to the layout and location(s) of the at least one first region 212 and the at least one second region 213. In particular, the layout and location(s) of the at least one first region 212 and the at least one second region 213 may correspond to a package structure 150 having a layout of semiconductor IC dies 105a, 105b as shown in FIG. 13A. The package substrate 201 may include a second region 213 in a central region of the array of bonding pads 209 of the package substrate 201. In the assembled semiconductor package 100, the second region 213 in the central region of the array of bonding pads 209 may underlie the central region of the package substrate 150. In particular, the second region 213 may underlie the central portion of the package substrate 150 where the pair of SoC dies 105a are adjacent to one another as shown in FIG. 13A. In various embodiments, the point labeled 317 in FIG. 13B may underlie the geometric center 217 of the package structure 150 in the assembled semiconductor package. In some embodiments, the second region 213 in the central region of the package substrate 201 may be circumscribed by a circle centered on point 317 and having a radius, R, where R may be ≤70% of the length dimension, L, and/or the width dimension, W, of the package structure 150.

The package substrate 201 may also include second regions 213 underlying the memory dies 105b in the assembled semiconductor package. Referring again to FIG. 13B, a pair of second regions 213 may be located in the upper left-hand corner and in the lower right-hand corner of the array of bonding pads 209 of the package substrate 201. These second regions 213 may underlie the memory dies 105b in the assembled semiconductor package. Unlike in the embodiment of FIGS. 9A-9C, these second regions 213 may only extend in the second horizontal direction hd2 along a portion of the peripheral edges of the array of bonding pads 209. In various embodiments, the processing operations described above with respect to FIGS. 10-12 may be performed to mount a package structure 150 having a layout of semiconductor IC dies 105a, 105b as shown in FIG. 13A to the package substrate 201 shown in FIG. 13B to form a semiconductor package 100.

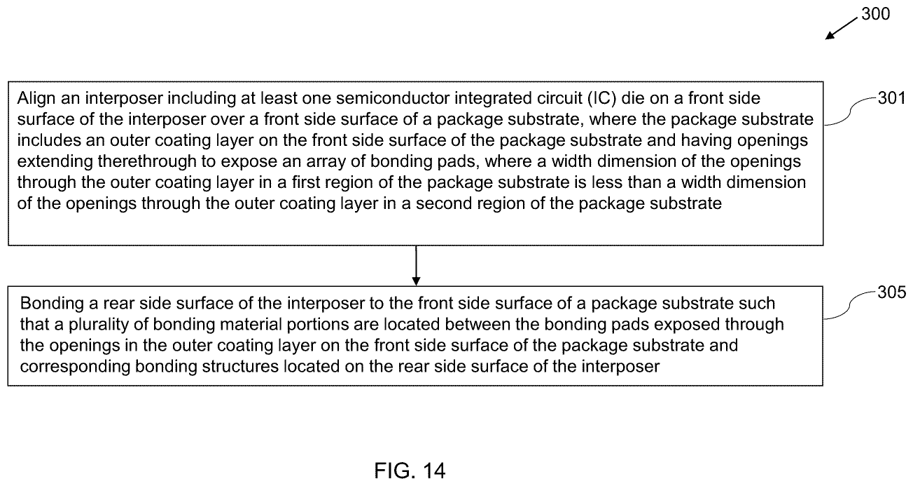

FIG. 14 is a flowchart illustrating a method 300 of fabricating a semiconductor package 100 according to various embodiments of the present disclosure. Referring to FIGS. 8-9C, 13A, 13B and 14, in step 301 of embodiment method 300, an interposer 103 having at least one semiconductor integrated circuit (IC) die 105a, 105b on a front side surface 102 of the interposer 103 may be aligned over a front side surface 202 of a package substrate 201, wherein the package substrate 201 includes an outer coating layer 210 on the front side surface 202 of the package substrate 201 and having first openings 222 and second openings 223 (collectively openings 211) extending therethrough to expose an array of bonding pads 209, where a first width dimension D₂₁₂ of the first openings 222 through the outer coating layer 210 in a first region 212 of the package substrate 201 is less than a second width dimension D₂₁₃ of the second openings 223 through the outer coating layer 210 in a second region 213 of the package substrate 201.

Referring to FIGS. 10A, 10B and 14, in step 305 of embodiment method 300, a rear side surface 104 of the interposer 103 may be bonded to the front side surface 202 of the package substrate 201 such that a plurality of bonding material portions 207 are located between the bonding pads 209 exposed through the openings 211 in the outer coating layer 210 on the front side surface 202 of the package substrate 201 and corresponding bonding structures 115 located on the rear side surface 104 of the interposer 103.

Referring to all drawings and according to various embodiments of the present disclosure, a semiconductor package 100 may include an interposer 103, at least one semiconductor integrated circuit (IC) die 105a, 105b mounted over a first surface 102 of the interposer 103, a package substrate 201 including an outer coating layer 210 on a front side surface 202 of the package substrate 201, the outer coating layer 210 having a plurality of first openings 222 and second openings 223 each exposing a bonding pad 209 of an array of bonding pads 209, and a first width dimension D₂₁₂ of the first openings 222 through the outer coating layer 210 in a first region 212 of the package substrate 201 is less than a second width dimension D₂₁₃ of the second openings 223 through the outer coating layer 210 in a second region 213 of the package substrate 201, and a plurality of bonding material portions 207 located between respective bonding pads 209 exposed through the first openings 222 and second openings 223 (collectively openings 211) in the outer coating layer 210 and corresponding bonding structures 115 located on the second surface 104 of the interposer 103.

In an embodiment, the outer coating layer 210 includes a solder resist layer, and the plurality of bonding material portions 207 include solder material portions.

In another embodiment, the at least one semiconductor IC die 105a, 105b includes a plurality of system-on-chip (SoC) dies 105a located in a central portion of interposer 103 and a plurality of memory dies 105b laterally surrounding the SoC dies 105a.

In another embodiment, the second region 213 of the package substrate 201 underlies the central portion of the interposer 103.

In another embodiment, the second region 213 of the package substrate 201 is circumscribed by a circle having a center underlying a geometric center of the interposer 103 and a radius R that is ≤70% of a length L or width W dimension of the interposer 103.

In another embodiment, the package substrate 201 includes a plurality of second regions 213, including a second region 213 underlying the plurality of SoC dies 105a located in a central portion of the interposer 103 and at least one second region 213 underlying the plurality of memory dies 105b.

In another embodiment, the package substrate 201 includes at least one second region 213 underlying a memory die 105b.

In another embodiment, the package substrate 201 includes second regions 213 extending along opposite peripheral edges of the array of bonding pads 209 and underlying memory dies 105b.

In another embodiment, each of the second regions 213 extending along opposite peripheral edges of the array of bonding pads 209 extend along the entire peripheral edges of the array of bonding pads 209.

In another embodiment, the second regions 213 extending along opposite peripheral edges of the array of bonding pads 209 extend over a portion of the peripheral edges of the array of bonding pads 209 and are located in opposite corners of the array of bonding pads 209.

In another embodiment, the bonding pads 209 in the first region 212 of the package substrate 201 include solder mask defined (SMD) bonding pads 209, and the bonding pads 209 in the second region 213 of the package substrate 201 include non-solder mask defined (NSMD) bonding pads 209.

In another embodiment, the locations of the first region 212 and the second region 213 of the package substrate 201 mitigate against warpage of the interposer 103.

In another embodiment, the interposer 103 includes an organic interposer 103 having at least four redistribution layers (RDLs).

An additional embodiment is drawn to a package substrate 201 including an array of bonding pads 209, each of the bonding pads 209 having a bonding pad width dimension D₂, and an outer coating layer 210 on a first side surface 202 of the semiconductor package 201, where the outer coating layer 210 includes a plurality of first openings 222 and a plurality of second openings 223 through the outer coating layer 210, each of the plurality of first opening 222 through the outer coating layer 210 having a first width dimension D₂₁₂ and exposing at least a portion of a bonding pad 209 of the array of bonding pads 209, each of the plurality of second opening 223 through the outer coating layer 210 having a second width dimension D₂₁₃ and exposing at least a portion of a bonding pad 209 of the array of bonding pads 209, where the bonding pad width dimension D₂ is greater than the first width dimension D₂₁₂ of the first openings 222 through the outer coating layer 210 in a first region 212 of the package substrate 201, and the bonding pad width dimension D₂ of the bonding pads 209 is less than the second width dimension D₂₁₃ of the second openings 223 through the outer coating layer 210 in a second region 213 of the package substrate 201.

In an embodiment, the second region 213 of the package substrate 201 is located in a central portion of the array of bonding pads 209.

In another embodiment, the second region 213 of the package substrate 201 is located along a peripheral edge of the array of bonding pads 209.

In another embodiment, the package substrate 201 includes a plurality of second regions 213, wherein the bonding pad width dimension D₂ of the bonding pads 209 is less than the second width dimension D₂₁₃ of the second openings 223 through the outer coating layer 210 in each of the second regions 213 of the package substrate 201, a second region 213 of the package substrate 201 is located in a central portion of the array of bonding pads 209, and a pair of second regions 213 of the package substrate 201 are located along opposite peripheral edges of the array of bonding pads 209.

In another embodiment, each of the second regions 213 extending along opposite peripheral edges of the array of bonding pads 209 extend along the entire peripheral edges of the array of bonding pads 209.

In another embodiment, each of the second regions 213 extending along opposite peripheral edges of the array of bonding pads 209 extend over a portion of the peripheral edges of the array of bonding pads 209 and are located in opposite corners of the array of bonding pads 209.

An additional embodiment is drawn to a method of fabricating a semiconductor package 100 that includes aligning an interposer 103 having at least one semiconductor integrated circuit (IC) die 105a, 105b on a front side surface 102 of the interposer 103 over a front side surface 202 of a package substrate 201, where the package substrate 201 includes an outer coating layer 210 on the front side surface 202 of the package substrate 201 and having a plurality of first openings 222 and a plurality of second openings 223 extending therethrough to expose an array of bonding pads 209, where a first width dimension D₂₁₂ of the first openings 222 through the outer coating layer 210 in a first region 212 of the package substrate 201 is less than a second width dimension D₂₁₃ of the second openings 223 through the outer coating layer 210 in a second region 213 of the package substrate 201, and bonding a rear side surface 104 of the interposer 103 to the front side surface 202 of the package substrate 201 such that a plurality of bonding material portions 207 are located between the bonding pads 209 exposed through the first openings 222 and second openings 223 (collectively openings 211) in the outer coating layer 210 on the front side surface 202 of the package substrate 201 and corresponding bonding structures 115 located on the rear side surface 104 of the interposer 103.

In an embodiment, bonding a rear side surface 104 of the interposer 103 to the front side surface 202 of the package substrate 201 includes performing a reflow process at a temperature greater than 150° C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer;
at least one semiconductor integrated circuit (IC) die mounted over a first surface of the interposer;
a package substrate comprising an outer coating layer on a front side surface of the package substrate, the outer coating layer having a plurality of first openings and second openings each exposing a bonding pad of an array of bonding pads, and a first width dimension of the first openings through the outer coating layer in a first region of the package substrate is less than a second width dimension of the second openings through the outer coating layer in a second region of the package substrate; and
a plurality of bonding material portions located between respective bonding pads exposed through the first openings and the second openings in the outer coating layer and corresponding bonding structures located on a second surface of the interposer.

2. The semiconductor package of claim 1, wherein the outer coating layer comprises a solder resist layer, and the plurality of bonding material portions comprise solder material portions.

3. The semiconductor package of claim 1, wherein the at least one semiconductor IC die comprises a plurality of system-on-chip (SoC) dies located in a central portion of interposer and a plurality of memory dies laterally surrounding the SoC dies.

4. The semiconductor package of claim 3, wherein the second region of the package substrate underlies a central portion of the interposer.

5. The semiconductor package of claim 4, wherein the second region of the package substrate is circumscribed by a circle having a center underlying a geometric center of the interposer and a radius that is ≤70% of a length or width dimension of the interposer.

6. The semiconductor package of claim 4, wherein the package substrate comprises a plurality of second regions, including a second region underlying the plurality of SoC dies located in a central portion of the interposer and at least one second region underlying the plurality of memory dies.

7. The semiconductor package of claim 3, wherein the package substrate comprises at least one second region underlying a memory die.

8. The semiconductor package of claim 7, wherein the package substrate comprises second regions extending along opposite peripheral edges of the array of bonding pads and underlying memory dies.

9. The semiconductor package of claim 8, wherein each of the second regions extending along opposite peripheral edges of the array of bonding pads extend along the entire peripheral edges of the array of bonding pads.

10. The semiconductor package of claim 8, wherein the second regions extending along opposite peripheral edges of the array of bonding pads extend over a portion of the peripheral edges of the array of bonding pads and are located in opposite corners of the array of bonding pads.

11. The semiconductor package of claim 2, wherein the bonding pads in the first region of the package substrate comprise solder mask defined (SMD) bonding pads, and the bonding pads in the second region of the package substrate comprise non-solder mask defined (NSMD) bonding pads.

12. The semiconductor package of claim 1, wherein the interposer comprises an organic interposer having at least four redistribution layers (RDLs).

13. A semiconductor package, comprising:
an array of bonding pads, each of the bonding pads having a bonding pad width dimension; and
an outer coating layer on a first side surface of the semiconductor package, wherein the outer coating layer comprises a plurality of first openings and second openings through the outer coating layer, each of the plurality of first openings through the outer coating layer having a first width dimension and exposing at least a portion of a bonding pad of the array of bonding pads, each of the plurality of second openings through the outer coating layer having a second width dimension and exposing at least a portion of a bonding pad of the array of bonding pads, wherein the bonding pad width dimension of the bonding pads is greater than the first width dimension of the first openings through the outer coating layer in a first region of the package substrate, and the bonding pad width dimension of the bonding pads is less than the second width dimension of the second openings through the outer coating layer in a second region of the package substrate.

14. The package substrate of claim 13, wherein the second region of the package substrate is located in a central portion of the array of bonding pads.

15. The package substrate of claim 13, wherein the second region of the package substrate is located along a peripheral edge of the array of bonding pads.

16. The package substrate of claim 13, wherein the package substrate comprises a plurality of second regions, wherein the width dimension of the bonding pads is less than the width dimension of the openings through the outer coating layer in each of the second regions of the package substrate, a second region of the package substrate is located in a central portion of the array of bonding pads, and a pair of second regions of the package substrate are located along opposite peripheral edges of the array of bonding pads.

17. The package substrate of claim 16, wherein each of the second regions extending along opposite peripheral edges of the array of bonding pads extend along the entire peripheral edges of the array of bonding pads.

18. The package substrate of claim 16, wherein each of the second regions extending along opposite peripheral edges of the array of bonding pads extend over a portion of the peripheral edges of the array of bonding pads and are located in opposite corners of the array of bonding pads.

19. A method of fabricating a semiconductor package, comprising:
aligning an interposer having at least one semiconductor integrated circuit (IC) die on a front side surface of the interposer over a front side surface of a package substrate, wherein the package substrate comprises an outer coating layer on the front side surface of the package substrate and having a plurality of first openings and a plurality of second openings extending therethrough to expose an array of bonding pads, where a first width dimension of the first openings through the outer coating layer in a first region of the package substrate is less than a second width dimension of the second openings through the outer coating layer in a second region of the package substrate; and
bonding a rear side surface of the interposer to the front side surface of the package substrate such that a plurality of bonding material portions are located between the bonding pads exposed through the plurality of first openings and the plurality of second in the outer coating layer on the front side surface of the package substrate and corresponding bonding structures located on the rear side surface of the interposer.

20. The method of claim 19, wherein bonding the rear side surface of the interposer to the front side surface of the package substrate comprises performing a reflow process at a temperature greater than 150° C.
